(19) United States
(12) Patent Application Publication
(10) Pub. No.: US 2026/0334223 A1
(43) Pub. Date: Oct. 22, 2026

(54) POWER SEMICONDUCTOR DEVICE INCLUDING A HIGH PERFORMANCE SUBSTRATE AND METHOD FOR FABRICATING THE SAME

(71) Applicant: Infineon Technologies AG, Neubiberg (DE)

(72) Inventors: Ivan Nikitin, Regensburg (DE); Andreas Grassmann, Sinzing (DE)

(21) Appl. No.: 19/557,774

(22) Filed: Mar. 5, 2026

(30) Foreign Application Priority Data
Mar. 17, 2025 (DE) 102025110044.6

(51) Int. Cl. H10W 40/25; H10W 70/40; H10W 74/10; H10W 90/00; H10W 90/10

(52) U.S. Cl. CPC H10W 40/254; H10W 70/458; H10W 74/111; H10W 90/10; H10W 90/734

(57) ABSTRACT

A power semiconductor device includes: a plurality of substrates, each including a first side and an opposite second side and having a thermal conductivity of 1 kW/(m·K) or more; a plurality of power semiconductor dies, each including a first side and an opposite second side, a respective one of the power semiconductor dies being arranged on each one of the plurality of substrates, such that the second side faces the first side of the respective substrate, each one of the power semiconductor dies being a SiC die or a GaN die; a metallization at least partially covering the first side of each of the substrates; a joining layer coupling the second side of each of the power semiconductor dies to the respective metallization; and an encapsulation encapsulating the plurality of power semiconductor dies.

### TECHNICAL FIELD

The present disclosure relates to power semiconductor devices, in particular to power semiconductor devices comprising a high performance substrate, as well as to methods for fabricating such power semiconductor devices.

### BACKGROUND

A power semiconductor device may comprise a substrate, a power semiconductor die arranged on the substrate and an encapsulation encapsulating the power semiconductor die. During operation, the power semiconductor die may generate a significant amount of heat. This heat has to be efficiently dissipated in order to prevent overheating of the power semiconductor device. The encapsulation regularly comprises a molded body or a plastic frame and a potting material. Such an encapsulation may exhibit a comparatively large thermal resistance and the main heat dissipation pathway of a power semiconductor device may therefore point from the power semiconductor die towards a heatsink through the substrate instead of through the encapsulation. The substrate not only has to provide good heat dissipation capabilities but also sufficient electrical insulation properties in order to isolate the power semiconductor die from the heatsink in a reliable manner. Commonly used substrates for this application are e.g. substrates of the type direct bonded copper (DBC) or active metal braze (AMB). These substrates comprise two metal layers separated by an insulating layer comprising e.g. silicon nitride, aluminum nitride or aluminum oxide. The electrical and thermal properties of these types of substrates have been considered well suited for the application in power semiconductor devices. However, continued technical advances lead to ever shrinking sizes of power semiconductor dies, which in turn leads to increased power densities in power semiconductor devices. In the case that the power semiconductor die is e.g. a Si die, a further reduction in die size may not be necessary due to the comparatively cheap fabrication costs of Si dies. However, in the case of comparatively expensive power semiconductor dies, like GaN dies or SiC dies, a point in the technological advance has now been reached where it is be desirable to use smaller dies and consequently higher power densities than possible with ordinary substrates. The fabrication process and/or the required mechanical stability of a substrate like a DBC or AMB may set a lower limit for the achievable thermal and electrical properties of these substrates. In order to fulfill the above-mentioned increasing requirements concerning the electrical and thermal properties, new types of substrates may have to be considered. These new types of substrates should have high mechanical stability, such that the substrates can be particularly thin without being damaged, in order to have as little a thermal resistance as possible. The substrate should have particularly high dielectric strength in order to provide reliable electrical insulation even at a very small thickness. At the same time, the substrate of course should also exhibit a high heat conductivity. Lastly, these new types of substrates should not be too expensive such that the cost benefit of being able to use smaller power semiconductor dies is not used up by a costlier substrate. Improved power semiconductor devices comprising such new substrates as well as improved methods for fabricating power semiconductor devices may help with solving these and other problems.

### SUMMARY

Various aspects pertain to a power semiconductor device, comprising: a substrate comprising a first side and an opposite second side, wherein the substrate has a thermal conductivity of 1 kW/(m·K) or more, a power semiconductor die comprising a first side and an opposite second side, the power semiconductor die arranged on the substrate such that the second side faces the first side of the substrate, wherein the power semiconductor die is a SiC die or a GaN die, a metallization at least partially covering the first side of the substrate, a joining layer coupling the second side of the power semiconductor die to the metallization, and an encapsulation encapsulating the power semiconductor die.

Various aspects pertain to a method for fabricating a power semiconductor device, the method comprising: providing a substrate comprising a first side and an opposite second side, wherein the substrate has a thermal conductivity of 1 kW/(m·K) or more, arranging a power semiconductor die comprising a first side and an opposite second side on the substrate such that the second side faces the first side of the substrate, wherein the power semiconductor die is a SiC die or a GaN die, at least partially covering the first side of the substrate with a metallization, coupling the second side of the power semiconductor die to the metallization with a joining layer, and encapsulating the power semiconductor die with an encapsulation.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a sectional view of a power semiconductor device comprising a power semiconductor die arranged on a substrate with a particularly high thermal conductivity. The power semiconductor die is a GaN die or a SiC die.

FIG. 2 illustrates a plan view of a further power semiconductor device comprising a plurality of power semiconductor dies that are each arranged on a single-die substrate.

FIG. 3 illustrates a detail view of one of the power semiconductor dies and the single-die substrates of the power semiconductor device of FIG. 2.

FIG. 4 shows a further power semiconductor device, according to another embodiment.

FIGS. 5A and 5B illustrate sectional views of two further power semiconductor devices, wherein an encapsulation of the power semiconductor device comprises a laminate. In the device illustrated in FIG. 5A, the substrate is exposed from the encapsulation and in the device illustrated in FIG. 5B, the substrate is completely encapsulated by the encapsulation.

FIG. 6 illustrates a sectional view of a substrate and a metallization arranged on the substrate, wherein the metallization comprises a stack of metal layers.

FIG. 7 illustrates a plan view of a substrate and a metallization according to a further example, wherein the metallization is a structured layer configured to accept a power semiconductor die with a lateral transistor structure.

FIG. 8 is a flow chart of an exemplary method for fabricating a power semiconductor device, wherein the power semiconductor device comprises a substrate with a particularly high thermal conductivity and wherein the power semiconductor die is a SiC die or a GaN die.

### DETAILED DESCRIPTION

In the following detailed description, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The examples of a power semiconductor device described below may use various types of semiconductor dies or circuits incorporated in the semiconductor dies, among them AC/DC or DC/DC converter circuits, power MOS transistors, power Schottky diodes, JFETs (Junction Gate Field Effect Transistors), power bipolar transistors, power integrated circuits, etc.

In several examples layers or layer stacks are applied to one another or materials are applied or deposited onto layers. It should be appreciated that any such terms as “applied” or “deposited” are meant to cover literally all kinds and techniques of applying layers onto each other. In particular, they are meant to cover techniques in which layers are applied at once as a whole like, for example, laminating techniques as well as techniques in which layers are deposited in a sequential manner like, for example, sputtering, plating, molding, CVD, etc.

An efficient power semiconductor device and an efficient method for fabricating a power semiconductor device may for example reduce material consumption, ohmic losses, chemical waste, etc. and may thus enable energy and/or resource savings. Improved power semiconductor devices and improved methods for fabricating a power semiconductor device, as specified in this description, may thus at least indirectly contribute to green technology solutions, i.e. climate-friendly solutions providing a mitigation of energy and/or resource use.

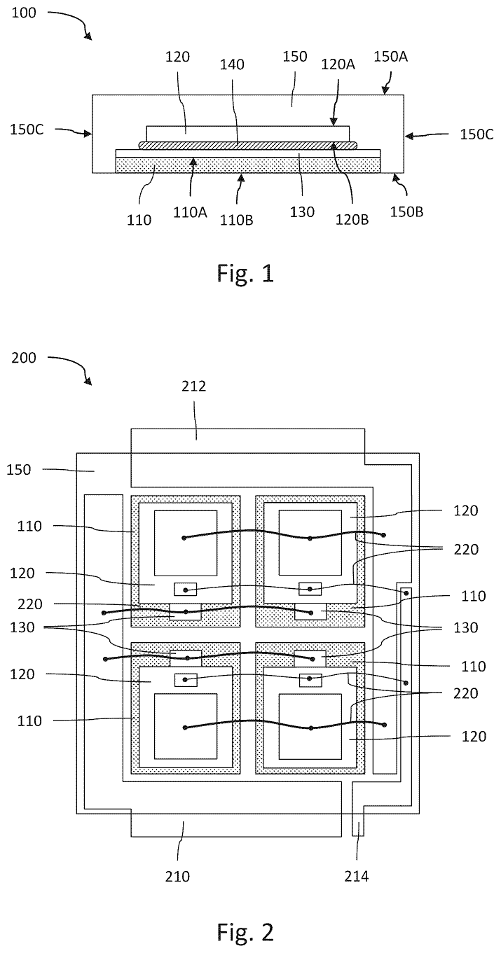

FIG. 1 schematically shows a sectional view of a power semiconductor device 100 comprising a substrate 110, a power semiconductor die 120, a metallization 130, a joining layer 140 and an encapsulation 150.

The power semiconductor device 100 may for example be a power semiconductor package or a power semiconductor module. According to an example, the power semiconductor device 100 may be a discrete device comprising a single power semiconductor die 120 or a single topological switch. According to another example, the power semiconductor device 100 may comprise a plurality of power semiconductor dies 120 connected to form a suitable electrical circuit, for example a half bridge circuit, a full bridge circuit, a converter circuit, an inverter circuit, etc. In the latter case, the power semiconductor dies 120 may all be the same type of die or different types of dies.

The power semiconductor device 100 may be configured to operate with a high voltage, e.g. a voltage of 100V or more, or 500V or more, or 1.2 kV or more, or even 2 kV or more. Furthermore, the power semiconductor device 100 may be configured to operate with a strong electrical current, for example a current of 1 A or more, or 10 A or more, or even 100 A or more.

The power semiconductor device 100 may be configured for use in any suitable application, for example automotive applications, industrial applications or household applications. According to a specific example, the power semiconductor package 100 is configured for use in the main inverter of an electric engine of an electric vehicle.

The substrate 110 comprises a first side 110A and an opposite second side 110B. The substrate 110 may have any suitable thickness measured between the first and second sides 110A, 110B. For example, the thickness may be in the range of about 50 μm to about 500 μm. The lower limit of this range may also be about 70 μm, or about 100 μm and the upper limit may also be about 300 μm, or about 200 μm.

The power semiconductor device 100, in particular the power semiconductor die 120, may generate a considerable amount of heat during operation. The substrate 110 may be part of a main heat dissipation pathway for dissipating this heat and may for example be configured to be coupled to a heatsink, such that the second side 110B of the substrate 110 faces the heatsink. The substrate 110 may in particular be configured to be coupled to a heatsink comprising or consisting of a baseplate and/or a fluid cooler.

In order to enable an efficient heat dissipation, the substrate 110 may have a particularly high thermal conductivity. Furthermore, the substrate 110 may be comparatively thin. According to an example, the substrate 110 is configured to also act as a heat spreader for heat generated by the power semiconductor die 120. Since the substrate 110 may also be configured to electrically insulate the power semiconductor die 120 towards the heatsink, the substrate 110 may have a comparably high dielectric strength.

The substrate 110 has a thermal conductivity of about 1 kW/(m·K) or more, or about 1.5 kW/(m·K) or more, or about 2 kW/(m·K) or more, or even about 2.2 kW/(m·K). According to an example, the substrate 110 has a dielectric strength of about 4 kV/100 μm or more, or about 5 kV/100 μm or more, or about 6 kV/100 μm.

According to an example, the substrate 110 comprises or consists of diamond. The substrate 110 may in particular consist of pure diamond, except for unavoidable contaminants. According to an example, the diamond is a monocrystalline diamond. According to another example, the diamond is a polycrystalline diamond.

Diamond has excellent thermal and dielectric properties. Industrial fabrication of diamond wafers with a diameter of 100 mm has become possible, significantly reducing the manufacturing costs. It is expected that it will soon be possible to manufacture wafers with even larger diameters, further reducing the costs of diamond substrates.

The power semiconductor die 120 comprises a first side 120A and an opposite second side 120B, wherein the power semiconductor die 120 is arranged on the substrate 110 such that the second side 120B faces the first side 110A of the substrate 110.

The power semiconductor die 120 may for example comprise a vertical transistor structure, wherein a first power electrode, e.g. a drain electrode or a collector electrode, is arranged on the first side 120A and a second power electrode, e.g. a source electrode or an emitter electrode, is arranged on the second side 120B. The positions of the first and second power electrodes may also be reversed. However, it is also possible that the power semiconductor die 120 comprises a lateral transistor structure, i.e. both the first power electrode and the second power electrode may be arranged on the same side, e.g. on the second side 120B.

The power semiconductor die 120 may for example be a Si die. However, according to a specific example, the power semiconductor die 120 is a SiC die or a GaN die. For a Si power semiconductor die, e.g. a Si IGBT (insulated-gate bipolar transistor) die it may not necessarily be cost efficient to use a comparably expensive substrate 110, like a diamond substrate. However, SiC dies or GaN dies may be comparatively expensive and it may therefore be desirable to use comparatively small dies. This increases the power density, which in turn makes a more efficient heat dissipation scheme necessary. Comparatively expensive high performance substrates, like diamond substrates, may therefore be particularly suitable for this use case.

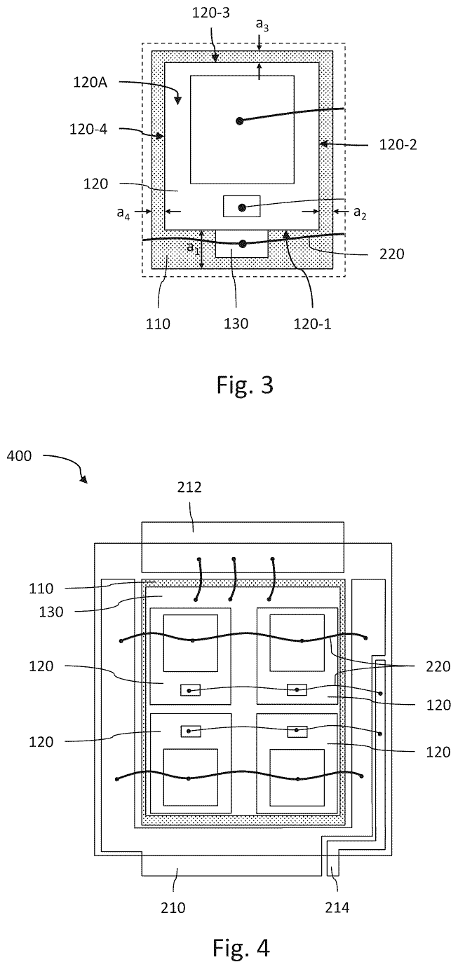

According to an example, a single power semiconductor die 120 is arranged on the substrate 110. In this case, the substrate 110 may have about the same size as the single power semiconductor die 120, as viewed from above the first side 120A of the power semiconductor die 120. This is explained in greater detail with respect to e.g. FIG. 3. According to another example, a plurality of power semiconductor dies 120 may be arranged on a common substrate 110. For example, two, three, four, five, six, etc. power semiconductor dies 120 may be arranged on a common substrate 110.

The metallization 130 at least partially covers the first side 110A of the substrate 110. The metallization 130 may also completely cover the first side 110A. The metallization 130 may be a structured layer, comprising conductive tracks and/or conductive islands separated by grooves. However, it is also possible that the metallization 130 is a non-structured layer (this may for example be the case if the second side 120B of the power semiconductor die 120 comprises only a single power electrode).

The metallization 130 may comprise or consist of any suitable metal or metal alloy. Furthermore, the metallization 130 may consist of a single metal layer or the metallization 130 may comprise a layer stack. The metallization 130 may for example comprise one or more of Ti, Ni, Ag and Cu.

The metallization 130 may have any suitable thickness measured perpendicular to the first side 110A of the substrate 110. For example, the thickness may be in the range of about 30 μm to about 500 μm. The lower limit of this range may also be about 50 μm, or about 70 μm, or about 100 μm and the upper limit may also be about 400 μm, or about 300 μm, or about 200 μm, or about 150 μm.

The metallization 130 may be deposited on the substrate 110 using any suitable deposition technique. For example, the metallization 130 may be deposited via sputtering or a vapor deposition process, e.g. chemical vapor deposition (CVD).

According to an example, only the first side 110A of the substrate 110 comprises the metallization 130. According to another example, a second metallization at least partially covers the second side 110B of the substrate 110. The second metallization may for example comprise or consist of the same material or material composition as the metallization 130. However, the second metallization may also have a different composition. Furthermore, a thickness of the second metallization may be in the range of thickness values mentioned above with respect to the metallization 130. The second metallization may for example be configured to be coupled to a heatsink.

The joining layer 140 couples the second side 120B of the power semiconductor die 120 to the metallization 140. The joining layer 140 may for example be a sintered layer, a solder layer or a layer comprising conductive glue. In the case of a solder layer, the joining layer 140 may for example be a soft solder layer or a reflow solder layer.

The joining layer 140 may comprise or consist of any suitable material or material composition. For example, the joining layer 140 comprises or consists of one or more of Ag, Au, Cu, Ni and Sn. The joining layer 140 may have any suitable thickness measured perpendicular to the first side 110A of the substrate 110, for example a thickness in the range of about 30 μm to about 500 μm. The lower limit of this range may also be about 50 μm, or about 100 μm and the upper limit of this range may also be about 400 μm, or about 300 μm, or about 200 μm.

The encapsulation 150 encapsulates the power semiconductor die 120. The encapsulation 150 may, for example, comprise or consist of a molded body. Such a molded body may for example be fabricated using a process like compression molding, injection molding or transfer molding. The encapsulation 150 may alternatively comprise or consist of a plastic frame with an interior volume, wherein the power semiconductor die 120 is arranged inside the interior volume and wherein the interior volume is at least partially filled with a suitable potting material.

The encapsulation 150 comprises a first side 150A, an opposite second side 150B and lateral sides 150C connecting the first and second sides 150A, 150B. According to an example, the substrate 110, in particular the second side 110B, may be exposed from the second side 150B of the encapsulation 150. In this manner, the second side 110B of the substrate 110 may be coupled to a heatsink.

The power semiconductor device 100 may comprise additional components not shown in FIG. 1. For example, the power semiconductor device 100 may comprise external terminals configured to provide an electrical connection to the power semiconductor die 120. The external terminals may for example comprise load terminals, configured to carry a load current, and control or sensing terminals, configured to carry a control or sensing signal. External terminals, in particular load terminals, may for example be exposed from one or more of the lateral sides 150C of the encapsulation 150. Control or sensing terminals may also be exposed from one or more of the lateral sides 150C or control or sensing terminals may be exposed from the first side 150A of the encapsulation 150. According to an example, no external terminals are exposed from the second side 150B.

FIG. 2 shows a plan view of a power semiconductor device 200 which may be similar or identical to the power semiconductor device 100, except for the differences described in the following.

The power semiconductor device 200 comprises a plurality of power semiconductor dies 120 arranged over a plurality of substrates 110. In particular, each power semiconductor die 120 is arranged over a separate substrate 110. In the example shown in FIG. 2, the power semiconductor device 200 comprises four power semiconductor dies 120 and consequently four separate substrates 110. However, the power semiconductor device 200 may of course also comprise for example two, six, eight, or any other suitable number of substrates 110 and corresponding power semiconductor dies 120.

As shown in FIG. 2, the substrates 110 may be arranged laterally next to each other. The substrates 110 may be arranged in a common plane. According to an example, the power semiconductor device 200 may comprise a carrier, wherein the substrates 110 are all arranged on the carrier. Such a carrier may for example comprise or consists of a metal pad, e.g. a Cu pad, a baseplate, etc. In this case, the substrates 110 may be configured to act as initial heat spreaders for heat generated by the individual power semiconductor dies 120 and the common carrier may for example be configured to act as a further heat spreader. The substrates 110 may for example be soldered, sintered or welded onto the common carrier.

The power semiconductor device 200 comprises a first external terminal 210, a second external terminal 212 and a third external terminal 214. The external terminals 210, 212, 214 may for example be parts of a leadframe. The first and second external terminals 210, 212 are load terminals, electrically connected to load electrodes of the power semiconductor dies 120, and the third external terminal 214 is a control terminal, connected to gate electrodes of the power semiconductor dies 120. The external terminals 210, 212, 214 may be connected to the electrodes of the power semiconductor dies 120 using electrical connectors 220. The electrical connectors 220 may, for example, comprise or consist of bond wires, ribbons or clips.

In the example shown in FIG. 2, the power semiconductor device 200 comprises four power semiconductor dies 120 connected in parallel. However, the power semiconductor device 200 may of course comprise any other suitable power electronic circuit.

FIG. 3 shows a detail view of a substrate 110 and a power semiconductor die 120 of the power semiconductor device 200.

The power semiconductor die 120 may comprise first to fourth lateral sides 120-1 to 120-4. As shown in FIG. 3, the substrate 110 may protrude from a contour of the power semiconductor die 120, as viewed from above the first side 120A of the power semiconductor die 120. The substrate 110 may in particular protrude from all four of the lateral sides 120-1 to 120-4 of the power semiconductor die 120.

According to an example, the substrate 110 protrudes from the first lateral side 120-1 by a first protrusion length a₁, from the second lateral side 120-2 by a second protrusion length a₂, from the third lateral side 120-3 by a third protrusion length a₃ and from the fourth lateral side 120-4 by a fourth protrusion length a₄. According to an example, the protrusion lengths a₁-a₄ are no more than 3 mm, or no more than 2 mm, or no more than 1 mm, or even no more than 0.5 mm. The protrusion lengths a₁-a₄ may all be essentially identical. However, it is also possible that one or more of the protrusion lengths a₁-a₄ is different from the rest.

In the example shown in FIG. 3, the protrusion length a₁ is greater than the protrusion lengths a₂-a₄ because the metallization 130 protrudes from under the power semiconductor die 120 at the first lateral side 120-1 in order to provide a contact pad for an electrical connector 220. It is of course also possible that the metallization 130 protrudes from under the power semiconductor die 120 at more than one of the lateral sides 120-1 to 120-4.

Generally speaking, the substrate 110 may have dimensions that are suitable for attaching only a single power semiconductor die 120. The substrate 110 may protrude to only a comparatively small amount from under the power semiconductor die 120 in order to provide heat spreading and/or to provide space for a contact pad of the metallization 130. This may help saving costs in the power semiconductor device 100 or 200 in the case that the substrate 110 is comparatively expensive.

FIG. 4 shows a further power semiconductor device 400, which may be similar or identical to the power semiconductor device 100 or 200, except for the differences described in the following.

In particular, the power semiconductor device 400 does not comprise single-die substrates 110 like the power semiconductor device 200 does. Instead, in the power semiconductor device 400 at least two power semiconductor dies 120 are arranged laterally next to each other on a common substrate 110. According to an example, the metallization 130 may be used to electrically connect the power semiconductor dies 120 on the common substrate 110 to each other and/or to one or more of the external terminals 210, 212, 214. In other words, the metallization 130 may act as a redistribution layer.

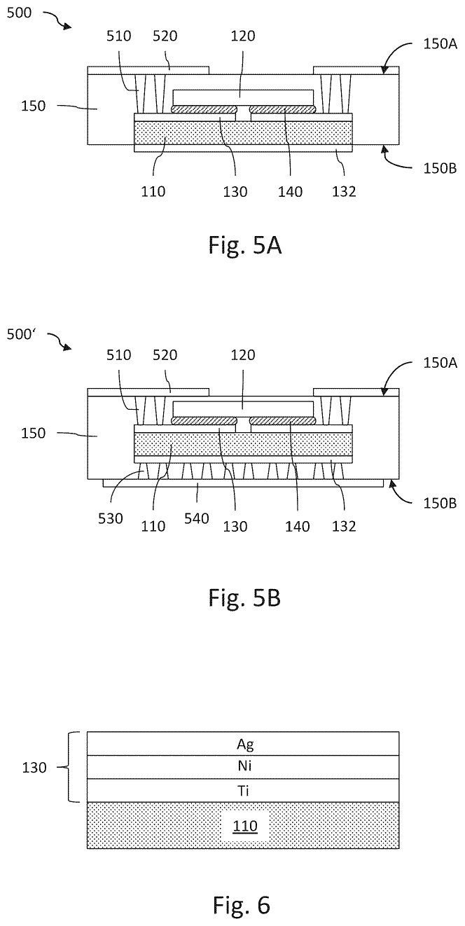

FIGS. 5A and 5B show further power semiconductor devices 500 and 500′, respectively. The power semiconductor devices 500 and 500′ may be similar or identical to any of the power semiconductor devices 100 to 400, except for the differences described in the following.

In particular, in the power semiconductor devices 500 and 500′, the encapsulation 150 may comprise or consist of a laminate. In particular, the encapsulation 150 may comprise or consist of a printed circuit board (PCB). In the power semiconductor device 500, the substrate 110 is exposed from the second side 150B of the encapsulation. In the power semiconductor device 500′, the substrate 110 is not exposed from the second side 150B.

The power semiconductor devices 500 and 500′ comprise first vias 510 connecting the metallization 130 to a first metal layer 520, wherein the first metal layer 520 is arranged on the first side 150A of the encapsulation 150. The power semiconductor devices 500 and 500′ may comprise a second metallization 132 at least partially covering the second side 110B of the substrates 110. The second metallization 132 may be configured to be coupled to a heatsink.

The power semiconductor device 500′ comprises second vias 530 extending from the second metallization 132 to a second metal layer 540 arranged on the second side 150B of the encapsulation 150. The exposed substrate 110 of the power semiconductor device 500 may exhibit superior thermal performance (i.e. heat dissipation capabilities), whereas encapsulating the substrate 110 as in the power semiconductor device 500′ provides a more symmetrical layout, which in turn may cause reduced warpage of the encapsulation 150.

FIG. 6 schematically shows a sectional view of the substrate 110 and the metallization 130 according to a specific example.

In the example shown in FIG. 6, the metallization 130 comprises a layer stack. The layer stack may comprise any suitable number of layers, wherein each layer of the stack may comprise any suitable metal or metal alloy. For example, the layer stack may comprise a Ti layer arranged directly on the substrate 110, a Ni layer arranged directly on the Ti layer and an Ag layer arranged directly on the Ni layer. According to an example, the metallization 130 comprises one or more additional layers, for example a Cu layer arranged directly on the Ag layer.

The layers of the metallization 130 may, for example, be deposited using a suitable sputtering process or a suitable vapor deposition process. In the case that the metallization 130 is a structured layer, structuring may for example comprise using a suitable photolithography process.

According to an example, the substrate 110 may be provided as part of a wafer, e.g. a diamond wafer and fabricating the substrate 110 comprises cutting the wafer. In this case, the metallization 130 may be arranged on the wafer prior to cutting, or the metallization 130 may be arranged on a singulated substrate 110.

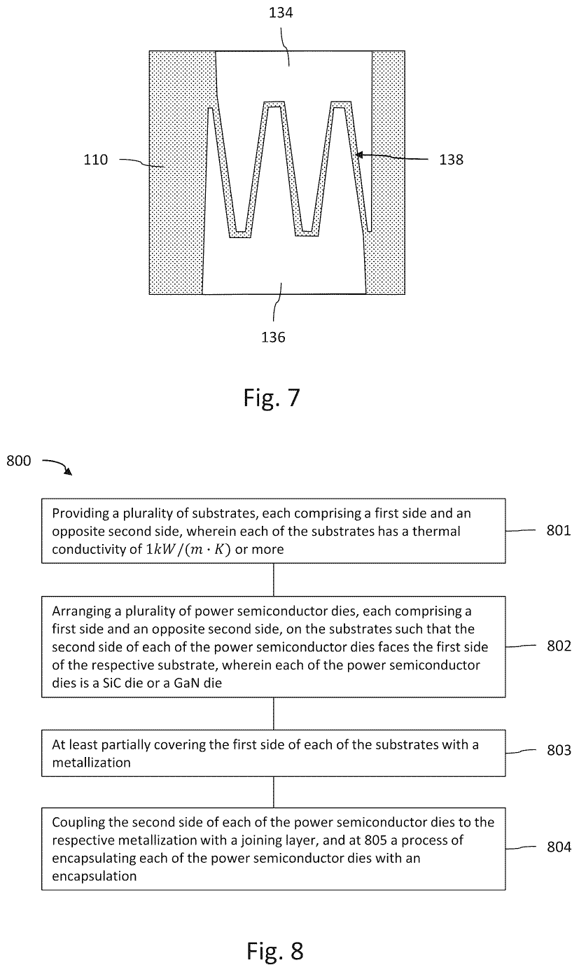

FIG. 7 schematically shows a plan view of the substrate 110 with a structured metallization 130, according to a specific example.

The substrate 110 of the example shown in FIG. 7 is a single-die substrate, meaning that the substrate 110 is configured to accept a single power semiconductor die 120. Furthermore, the metallization 130 is structured in a manner that is adapted for a power semiconductor die 120 that comprises a lateral transistor structure. The metallization 130 comprises a first contact pad 134 and a second contact pad 136 separated by a groove 138, wherein the first contact pad 134 may be coupled to a first power electrode and the second contact pad 136 may be coupled to a second power electrode of the power semiconductor die 120.

The contact pads 134, 136 of the specific example of the metallization 130 shown in FIG. 7 comprise a saw tooth contour. Such a design of the metallization 130 may e.g. be configured for use with a GaN die or a SiC die.

As noted further above, the metallization 130 may be comparably thin and may in particular be thinner than the metallization of e.g. a DCB or an AMB. For this reason, finer structures, e.g. a finer groove 138 and/or finer saw tooth structures, may be fabricated in the metallization 130 than in the metallization of a DCB or an AMB (design rules for layer structuring roughly demand a 1:1 ratio between layer thickness and structure size).

FIG. 8 is a flow chart of an exemplary method 800 for fabricating a power semiconductor device. The method 800 may for example be used to fabricate any of the power semiconductor devices 100 to 500′.

The method 800 comprises at 801 a process of providing a plurality of substrates, each comprising a first side and an opposite second side, wherein each of the substrates has a thermal conductivity of 1 kW/(m·K) or more, at 802 a process of arranging a plurality of power semiconductor dies, each comprising a first side and an opposite second side, on the substrates such that the second side of each of the power semiconductor dies faces the first side of the respective substrate, wherein each of the power semiconductor dies is a SiC die or a GaN die, at 803 a process of at least partially covering the first side of each of the substrates with a metallization, at 804 a process of coupling the second side of each of the power semiconductor dies to the respective metallization with a joining layer, and at 805 a process of encapsulating each of the power semiconductor dies with an encapsulation.

According to an example of the method 800, the process 803 of at least partially covering the first side of each of the substrates with the respective metallization comprises sputtering or vapor depositing a metallization layer directly onto diamond.

In the following, the power semiconductor device and the method for fabricating a power semiconductor device are further explained using specific examples.

Example 1 is a power semiconductor device, comprising: a substrate comprising a first side and an opposite second side, wherein the substrate has a thermal conductivity of 1 kW/(m·K) or more, a power semiconductor die comprising a first side and an opposite second side, the power semiconductor die arranged on the substrate such that the second side faces the first side of the substrate, wherein the power semiconductor die is a SiC die or a GaN die, a metallization at least partially covering the first side of the substrate, a joining layer coupling the second side of the power semiconductor die to the metallization, and an encapsulation encapsulating the power semiconductor die.

Example 2 is the power semiconductor device of example 1, wherein the substrate has a thermal conductivity of 2 kW/(m·K) or more.

Example 3 is the power semiconductor device of example 1 or 2, wherein the substrate has a dielectric strength of 5 kV/100 μm or more.

Example 4 is the power semiconductor device of one of the preceding examples, wherein the substrate is a diamond substrate.

Example 5 is the power semiconductor device of example 4, wherein the substrate consists of pure diamond, except for unavoidable contaminants.

Example 6 is the power semiconductor device of example 5, wherein the diamond is a monocrystal, or wherein the diamond is a polycrystal.

Example 7 is the power semiconductor device of one of examples 4 to 6, wherein the metallization comprises a layer sputtered or vapor-deposited directly onto the diamond.

Example 8 is the power semiconductor device of example 7, wherein the sputtered or a vapor-deposited layer is a Ti layer or a Ni layer.

Example 9 is the power semiconductor device of one of the preceding examples, wherein the metallization has a thickness of 100 μm or less, measured perpendicular to the first side of the substrate.

Example 10 is the power semiconductor device of one of the preceding examples, further comprising: a second metallization at least partially covering the second side of the substrate, the second metallization configured to be coupled to a heatsink.

Example 11 is the power semiconductor device of one of the preceding examples, further comprising: a second power semiconductor die arranged on the substrate laterally next to the power semiconductor die.

Example 12 is the power semiconductor device of one of examples 1 to 10, wherein the substrate protrudes from a contour of the power semiconductor die, as viewed from above the first side of the power semiconductor die, by no more than 3 mm, in particular by no more than 0.5 mm.

Example 13 is the power semiconductor device of example 12, further comprising: a second substrate arranged laterally next to the substrate, and a second power semiconductor die arranged on the second substrate.

Example 14 is the power semiconductor device of one of the preceding examples, further comprising: a leadframe comprising external contacts of the power semiconductor device, wherein at least one of the external contacts is connected to the metallization via a clip, a ribbon or a bond wire.

Example 15 is the power semiconductor device of one of the preceding examples, wherein the joining layer is a solder layer or a sintered layer.

Example 16 is a method for fabricating a power semiconductor device, the method comprising: providing a substrate comprising a first side and an opposite second side, wherein the substrate has a thermal conductivity of 1 kW/(m·K) or more, arranging a power semiconductor die comprising a first side and an opposite second side on the substrate such that the second side faces the first side of the substrate, wherein the power semiconductor die is a SiC die or a GaN die, at least partially covering the first side of the substrate with a metallization, coupling the second side of the power semiconductor die to the metallization with a joining layer, and encapsulating the power semiconductor die with an encapsulation.

Example 17 is the method of example 16, wherein the substrate is a diamond substrate.

Example 18 is the method of example 17, wherein the substrate consists of pure diamond, except for unavoidable contaminants.

Example 19 is the method of example 17 or 18, wherein at least partially covering the first side of the substrate with the metallization comprises sputtering or vapor depositing a metallization layer directly onto the diamond.

Example 20 is an apparatus comprising means for performing the method according to anyone of examples 16 to 19.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A power semiconductor device, comprising:
a plurality of substrates, each comprising a first side and an opposite second side, wherein each of the substrates has a thermal conductivity of 1 kW/(m·K) or more;
a plurality of power semiconductor dies, each comprising a first side and an opposite second side, a respective one of the power semiconductor dies arranged on each one of the plurality of substrates, such that the second side faces the first side of the respective substrate, wherein each one of the power semiconductor dies is a SiC die or a GaN die;
a metallization at least partially covering the first side of each of the substrates;
a joining layer coupling the second side of each of the power semiconductor dies to the respective metallization; and
an encapsulation encapsulating the plurality of power semiconductor dies.

2. The power semiconductor device of claim 1, wherein each of the substrates has a thermal conductivity of 2 kW/(m·K) or more.

3. The power semiconductor device of claim 1, wherein each of the substrates has a dielectric strength of 5 kV/100 μm or more.

4. The power semiconductor device of claim 1, wherein each of the substrates is a diamond substrate.

5. The power semiconductor device of claim 4, wherein each of the substrates consists of pure diamond, except for unavoidable contaminants.

6. The power semiconductor device of claim 5, wherein the diamond is a monocrystal or a polycrystal.

7. The power semiconductor device of claim 4, wherein the metallization of each of the substrates comprises a layer sputtered or vapor-deposited directly onto the diamond.

8. The power semiconductor device of claim 7, wherein the sputtered or vapor-deposited layer is a Ti layer or a Ni layer.

9. The power semiconductor device of claim 1, wherein the metallization of each of the substrates has a thickness of 100 μm or less, measured perpendicular to the first side of the respective substrate.

10. The power semiconductor device of claim 1, further comprising:
a second metallization at least partially covering the second side of each of the substrates, the second metallization configured to be coupled to a heatsink.

11. The power semiconductor device of claim 1, wherein each of the substrates protrudes from a contour of the respective power semiconductor die, as viewed from above the first side of the power semiconductor die, by no more than 3 mm.

12. The power semiconductor device of claim 1, wherein the substrates are arranged laterally next to each other in a common plane.

13. The power semiconductor device of claim 1, further comprising:
a leadframe comprising external terminals of the power semiconductor device,
wherein at least one of the external terminals is connected to the metallization of at least one of the substrates via a clip, a ribbon or a bond wire.

14. The power semiconductor device of claim 1, wherein the joining layer is a solder layer or a sintered layer.

15. A method for fabricating a power semiconductor device, the method comprising:
providing a plurality of substrates, each comprising a first side and an opposite second side, wherein each of the substrates has a thermal conductivity of 1 kW/(m·K) or more;
arranging a plurality of power semiconductor dies, each comprising a first side and an opposite second side, on the substrates such that the second side of each of the power semiconductor dies faces the first side of the respective substrate, wherein each of the power semiconductor dies is a SiC die or a GaN die;
at least partially covering the first side of each of the substrates with a metallization;
coupling the second side of each of the power semiconductor dies to the respective metallization with a joining layer; and
encapsulating each of the power semiconductor dies with an encapsulation.

16. The method of claim 15, wherein each of the substrates is a diamond substrate.

17. The method of claim 16, wherein each of the substrates consists of pure diamond, except for unavoidable contaminants.

18. The method of claim 16, wherein at least partially covering the first side of each of the substrates with the respective metallization comprises sputtering or vapor depositing a metallization layer directly onto the diamond.
